(19) United States
(12) Patent Application Publication
(10) Pub. No.: US 2018/0138335 A1
(43) Pub. Date: May 17, 2018

(54) FRONT ELECTRODE FOR SOLAR CELL AND SOLAR CELL COMPRISING THE SAME

(71) Applicant: SAMSUNG SDI CO., LTD., Yongin-si (KR)

(72) Inventors: Yong Hyun KIM, Suwon-si (KR); Young Kwon KOO, Suwon-si (KR); Jae Joon SHIM, Suwon-si (KR); Sang Hoon YOO, Suwon-si (KR); Jung Chul LEE, Suwon-si (KR); Ryun Min HEO, Suwon-si (KR)

(21) Appl. No.: 15/618,710

(22) Filed: Jun. 9, 2017

(30) Foreign Application Priority Data
Nov. 11, 2016 (KR) 10-2016-0150639

(51) Int. Cl. H01L 31/0224; H01L 31/0216

(52) U.S. Cl. CPC H01L 31/022433; H01L 31/02168

(57) ABSTRACT

A front electrode for a solar cell includes a substrate, a first conductive layer on the substrate, and a second conductive layer on the first conductive layer. The second conductive layer is formed of a composition including silver powder as a first metal powder; and at least one of tin powder, lead powder, and bismuth powder as a second metal powder. The second metal powder is present in an amount of about 0.1 wt % to about 15 wt % based on the total weight of the first conductive layer and the second conductive layer in an unbaked state of the first conductive layer and the second conductive layer.

### CROSS-REFERENCE TO RELATED APPLICATION

Korean Patent Application No. 10-2016-0150639, filed on Nov. 11, 2016, in the Korean Intellectual Property Office, and entitled: “Front Electrode for Solar Cell and Solar Cell Comprising the Same,” is incorporated by reference herein in its entirety.

### BACKGROUND

### 1. Field

Embodiments relate to a front electrode for a solar cell and a solar cell including the same. More particularly, the present invention relates to.

### 2. Description of the Related Art

Solar cells generate electricity using the photovoltaic effect of a p-n junction which converts photons of sunlight into electricity. In the solar cell, front and rear electrodes are formed on upper and lower surfaces of a semiconductor wafer or substrate with the p-n junctions, respectively. Then, the photovoltaic effect at the p-n junction is induced by sunlight entering the semiconductor wafer and electrons generated by the photovoltaic effect at the p-n junction provide electric current to the outside through the electrodes.

### SUMMARY

Embodiments are directed to a front electrode for a solar cell, the front electrode including a substrate, a first conductive layer on the substrate, and a second conductive layer on the first conductive layer. The second conductive layer is formed of a composition including silver powder as a first metal powder; and at least one of tin powder, lead powder, and bismuth powder as a second metal powder. The second metal powder is present in an amount of about 0.1 wt % to about 15 wt % based on the total weight of the first conductive layer and the second conductive layer in an unbaked state of the first conductive layer and the second conductive layer.

The second metal powder may have an average particle diameter (D50) of about 0.1 μm to about 3 μm.

The composition from which the second conductive layer is formed may include about 60 wt % to about 95 wt % of the first metal powder, about 0.1 wt % to about 20 wt % of the second metal powder, about 0.5 wt % to about 20 wt % of a glass fit, and about 1 wt % to about 30 wt % of an organic vehicle.

The composition from which the second conductive layer is formed may further include at least one additive of a dispersant, a thixotropic agent, a plasticizer, a viscosity stabilizer, an anti-foaming agent, a pigment, a UV stabilizer, an antioxidant, and a coupling agent.

The first conductive layer may be formed of a composition that includes the first metal powder and does not include the second metal powder.

Embodiments are also directed to a solar cell including the front electrode as described above.

### BRIEF DESCRIPTION OF DRAWINGS

Features will become apparent to those of skill in the art by describing in detail exemplary embodiments with reference to the attached drawings in which:

FIGS. 1 and 2 illustrate a schematic views of a solar cell according to an embodiment.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing figures, the dimensions of layers and regions may be exaggerated for clarity of illustration. Like reference numerals refer to like elements throughout.

According to an embodiment, a front electrode for a solar cell (hereinafter referred to as a “front electrode”) is provided.

The front electrode may includes a substrate, a first conductive layer formed on the substrate, and a second conductive layer formed on the first conductive layer. The second conductive layer may be formed of a composition including silver powder as a first metal powder and at least one of tin powder, lead powder, and bismuth powder as a second metal powder. The second conductive powder may be present in an amount of about 0.1 wt % to about 15 wt %. For example, the second powder may be present in an amount of 0.1 wt %, 1 wt %, 2 wt %, 3 wt %, 4 wt %, 5 wt %, 6 wt %, 7 wt %, 8 wt %, 9 wt %, 10 wt %, 11 wt %, 12 wt %, 13 wt %, 14 wt %, or 15 wt %, in the front electrode.

Second Conductive Layer

The second conductive layer may be formed of a conductive composition including a conductive powder, a glass frit, and an organic vehicle.

Conductive Powder

The conductive powder may include a first metal powder and a second metal powder.

The conductive powder may include silver (Ag) powder as the first metal powder. The particle size of the silver powder may be on a nanometer or micrometer scale. For example, the silver powder may have a particle size of dozens to several hundred nanometers, or several to dozens of micrometers. In some implementations, the silver powder may be a mixture of two or more types of silver powders having different particle sizes.

The silver powder may have a spherical, flake or amorphous shape.

The silver powder may have, for example, an average particle diameter (D50) of about 0.1 μm to about 3 μm, or, for example, about 0.5 μm to about 2 μm. For example, the silver powder may have an average particle diameter (D50) of about 0.5 μm, 0.6 μm, 0.7 μm, 0.8 μm, 0.9 μm, 1.0 μm, 1.1 μm, 1.2 μm, 1.3 μm, 1.4 μm, 1.5 μm, 1.6 μm, 1.7 μm, 1.8 μm, 1.9 μm, or 2.0 μm. Within this range of average particle diameter, the composition may provide low contact resistance and low line resistance. The average particle diameter (D50) may be measured using, for example, a Model 1064D (CILAS Co., Ltd.) after dispersing the conductive powder in isopropyl alcohol (IPA) at 25° C. for 3 minutes via ultrasonication.

The first metal powder may be present in an amount of about 60 wt % to about 95 wt % based on the total weight of the composition for the second conductive layer. Within this range, the first metal powder may prevent deterioration in conversion efficiency due to increase in resistance and difficulty in forming a paste due to relative reduction in amount of the organic vehicle. The first metal powder may be present, for example, in an amount of about 70 wt % to about 90 wt % based on the total weight of the composition for the second conductive layer. For example, the first metal powder may be present in an amount of 70 wt %, 71 wt %, 72 wt %, 73 wt %, 74 wt %, 75 wt %, 76 wt %, 77 wt %, 78 wt %, 79 wt %, 80 wt %, 81 wt %, 82 wt %, 83 wt %, 84 wt %, 85 wt %, 86 wt %, 87 wt %, 88 wt %, 89 wt %, or 90 wt %, based on the total weight of the composition for the second conductive layer.

The first metal powder may be present in an amount of about 80 wt % to about 99.9%, of, for example, about 85 wt % to about 99.9 wt % based on the total weight of the first metal powder and the second metal powder. For example, the first metal powder may be present in an amount of 85 wt %, 86 wt %, 87 wt %, 88 wt %, 89 wt %, 90 wt %, 91 wt %, 92 wt %, 93 wt %, 94 wt %, 95 wt %, 96 wt %, 97 wt %, 98 wt %, 99 wt %, or 99.9 wt %, based on the total weight of the first metal powder and the second metal powder. Within this range, the front metal powder may provide excellent conversion efficiency and high tensile strength.

The conductive powder may include at least one of tin powder, lead powder, and bismuth powder as the second metal powder.

The front electrode for a solar cell may include the first conductive layer and the second conductive layer The second metal powder may be included only in the second conductive layer. For a given amount of metal powder, the front electrode for a solar cell according to embodiments may provide cell efficiency higher than or equal to that of a front electrode including only the first metal powder. In the front electrode a solar cell according to embodiments, the second conductive powder may be present in an amount of about 0.1 wt % to about 15 wt %, or, for example, 0.1 wt %, 1 wt %, 2 wt %, 3 wt %, 4 wt %, 5 wt %, 6 wt %, 7 wt %, 8 wt %, 9 wt %, 10 wt %, 11 wt %, 12 wt %, 13 wt %, 14 wt %, or 15 wt %, based on the total weight of the first conductive layer and the second conductive layer before baking. Within this range, the second conductive powder may increase the tensile strength of the front electrode, thereby improving long-term reliability of the solar cell. As used herein, the term “long-term reliability” indicates that it is possible to prevent a ribbon or the like from being separated when a solar cell is subjected to a thermal shock test from a high temperature to a low temperature and from a low temperature to a high temperature. In the front electrode, the second metal powder may be present in an amount of, for example, about 0.1 wt % to about 10 wt %, or, for example, 0.1 wt %, 1 wt %, 2 wt %, 3 wt %, 4 wt %, 5 wt %, 6 wt %, 7 wt %, 8 wt %, 9 wt %, or 10 wt % before baking. The front electrode may have a tensile strength of about 2.5 N/mm or more, or, for example about 2.8 N/mm to about 5.0 N/mm, about 3.0 N/mm to about 5.0 N/mm, or, for example, 3.0 N/mm, 4.0 N/mm, or 5.0 N/mm. Within this range, a solar cell including the front electrode may have excellent long-term reliability.

In addition, the second metal powder may reduce a sintering temperature of the composition to improve sinterability, thereby enhancing the efficiency of a solar cell.

The second metal powder may have an average particle diameter (D50) of, for example, about 0.1 μm to about 3 μm, or, for example, about 0.5 μm to about 3 μm, or, for example, 0.5 μm, 1.5 μm, 2 μm, 2.5 μm, or 3 μm. Within this range, the composition may provide low contact resistance and low line resistance. The average particle diameter may be measured in the same manner as that of the first metal powder.

The second metal powder may be present in an amount of about 0.1 wt % to about 20 wt %, or for example, 0.1 wt %, 1 wt %, 2 wt %, 3 wt %, 4 wt %, 5 wt %, 6 wt %, 7 wt %, 8 wt %, 9 wt %, 10 wt %, 11 wt %, 12 wt %, 13 wt %, 14 wt %, 15 wt %, 16 wt %, 17 wt %, 18 wt %, 19 wt %, or 20 wt %, based on the total weight of the composition for the second conductive layer. Within this range, the second metal powder may increase the tensile strength of the front electrode after baking while preventing reduction in electrode efficiency. The second metal powder is present in an amount of, for example, about 0.1 wt % to about 15 wt %, or about 5 wt % to about 15 wt % based on the total weight of the composition for the second conductive layer. For example, the second metal powder may be present in an amount of 5 wt %, 6 wt %, 7 wt %, 8 wt %, 9 wt %, 10 wt %, 11 wt %, 12 wt %, 13 wt %, 14 wt %, or 15 wt %, based on the total weight of the composition for the second conductive layer.

The second metal powder may be present in an amount of about 0.1 wt % to about 15 wt %, or, for example, about 0.1 wt % to about 10 wt %, based on the total weight of the first conductive layer and the second conductive layer of the front electrode before baking. For example, the second metal powder may be present in an amount of 0.1 wt %, 1 wt %, 2 wt %, 3 wt %, 4 wt %, 5 wt %, 6 wt %, 7 wt %, 8 wt %, 9 wt %, or 10 wt %, based on the total weight of the first conductive layer and the second conductive layer of the front electrode before baking. Within this range, the front electrode may have excellent efficiency while exhibiting improved tensile strength.

Glass Frit

The glass frit may serve to enhance adhesion between the conductive powder and the wafer or the substrate and to form silver crystal grains in an emitter region by etching an anti-reflection layer and melting the silver powder so as to reduce contact resistance during the baking process of an electrode paste. Further, during the baking process, the glass frit may soften and decrease the baking temperature.

When the area of a solar cell is increased in order to improve solar cell efficiency, solar cell contact resistance may increase. Thus, it is desirable to minimize both serial resistance (Rs) and influence on the p-n junction. In addition, the baking temperature may vary within a broad range with increasing use of various wafers having different sheet resistances. Accordingly, it is desirable that the glass frit secure sufficient thermal stability to withstand a wide range of baking temperatures.

The glass fit may be a suitable glass frit used in a paste for a solar cell electrode. For example, the glass frit may be a leaded glass frit or a lead-free glass frit.

The glass frit may include at least one metal oxide selected from lead oxide, silicon oxide, tellurium oxide, bismuth oxide, zinc oxide, boron oxide, aluminum oxide, tungsten oxide, and combinations thereof. For example, the glass frit may be any one of zinc oxide-silicon oxide (ZnO—SiO₂), zinc oxide-boron oxide-silicon oxide (ZnO—B₂O₃—SiO₂), zinc oxide-boron oxide-silicon oxide-aluminum oxide (ZnO—B₂O₃—SiO₂—Al₂O₃), bismuth oxide-silicon oxide (Bi₂O₃—SiO₂), bismuth oxide-boron oxide-silicon oxide (Bi₂O₃—B₂O₃—SiO₂), bismuth oxide-boron oxide-silicon oxide-aluminum oxide (Bi₂O₃—B₂O₃—SiO₂—Al₂O₃), bismuth oxide-zinc oxide-boron oxide-silicon oxide (Bi₂O₃—ZnO—B₂O₃—SiO₂), bismuth oxide-zinc oxide-boron oxide-silicon oxide-aluminum oxide (Bi₂O₃—ZnO—B₂O₃—SiO₂—Al₂O₃), lead oxide-tellurium oxide (PbO—TeO₂), lead oxide-tellurium oxide-silicon oxide (PbO—TeO₂-SiO₂), lead oxide-tellurium oxide-lithium oxide (PbO—TeO₂—Li₂O), bismuth oxide-tellurium oxide (Bi₂O₃—TeO₂), bismuth oxide-tellurium oxide-silicon oxide (Bi₂O₃—TeO₂—SiO₂), tellurium oxide-zinc oxide (TeO₂—ZnO), and bismuth oxide-tellurium oxide-lithium oxide (Bi₂O₃—TeO₂—Li₂O) glass frits.

The glass fit may be prepared from such metal oxides by a suitable method. For example, the metal oxides may be mixed in a predetermined ratio. Mixing may be carried out using a ball mill or a planetary mill. The mixture may be melted at 700° C. to 1300° C., followed by quenching to 25° C. The obtained resultant may be subjected to pulverization using a disk mill, a planetary mill, or the like, thereby preparing a glass frit.

The glass frit may have an average particle diameter (D50) of about 0.1 μm to about 10 μm, or, for example, 0.1 μm, 1 μm, 2 μm, 3 μm, 4 μm, 5 μm, 6 μm, 7 μm, 8 μm, 9 μm, or 10 μm. The glass fit may be present in an amount of about 0.5 wt % to about 20 wt %, or, for example, 0.5 wt %, 1 wt %, 2 wt %, 3 wt %, 4 wt %, 5 wt %, 6 wt %, 7 wt %, 8 wt %, 9 wt %, 10 wt %, 11 wt %, 12 wt %, 13 wt %, 14 wt %, 15 wt %, 16 wt %, 17 wt %, 18 wt %, 19 wt %, or 20 wt %, based on the total weight of the composition for the second conductive layer. The glass frit may have a spherical or amorphous shape. In an embodiment, a mixture of two types of glass frits having different glass transition points may be used for the composition.

Organic Vehicle

The organic vehicle imparts suitable viscosity and rheological characteristics for printing to the paste for solar cell electrodes through mechanical mixing with inorganic components of the paste.

The organic vehicle may be a suitable organic vehicle used in solar cell electrode pastes. The organic vehicle may include a binder resin, a solvent, or the like.

The binder resin may be selected from acrylate resins or cellulose resins. For example, ethyl cellulose may be used as the binder resin. In some implementations, the binder resin may be ethyl hydroxyethyl cellulose, nitrocellulose, blends of ethyl cellulose and phenol resins, alkyd, phenol, acrylate ester, xylene, polybutane, polyester, urea, melamine, vinyl acetate resins, wood rosin, polymethacrylates of alcohols, or the like.

The solvent may be selected from, for example, hexane, toluene, ethyl cellosolve, cyclohexanone, butyl cellosolve, butyl carbitol (diethylene glycol monobutyl ether), dibutyl carbitol (diethylene glycol dibutyl ether), butyl carbitol acetate (diethylene glycol monobutyl ether acetate), propylene glycol monomethyl ether, hexylene glycol, terpineol, methylethylketone, benzylalcohol, γ-butyrolactone, ethyl lactate, and combinations thereof.

The organic vehicle may be present in an amount of about 1 wt % to about 30 wt %, or, for example, 1 wt %, 2 wt %, 3 wt %, 4 wt %, 5 wt %, 6 wt %, 7 wt %, 8 wt %, 9 wt %, 10 wt %, 11 wt %, 12 wt %, 13 wt %, 14 wt %, 15 wt %, 16 wt %, 17 wt %, 18 wt %, 19 wt %, 20 wt %, 21 wt %, 22 wt %, 23 wt %, 24 wt %, 25 wt %, 26 wt %, 27 wt %, 28 wt %, 29 wt %, or 30 wt %, based on the total weight of the composition for the second conductive layer. Within this range, the organic vehicle may provide sufficient adhesive strength and excellent printability to the composition.

The composition for the second conductive layer may further include general additives, as needed, to enhance flow properties, process properties, and stability. The additives may include dispersants, thixotropic agents, plasticizers, viscosity stabilizers, anti-foaming agents, pigments, UV stabilizers, antioxidants, coupling agents, or the like. These additives may be used alone or as mixtures thereof. The additives may be present in an amount of about 0.1 wt % to about 5 wt %, or, for example, 0.1 wt %, 1 wt %, 2 wt %, 3 wt %, 4 wt %, or 5 wt %, based on the total weight of the composition for the second conductive layer.

First Conductive Layer

The first conductive layer is formed to directly adjoin both the second conductive layer and the substrate.

The first conductive layer may be formed of a conductive layer composition including a conductive powder, a glass fit, and an organic vehicle.

The conductive powder may include silver (Ag), gold (Au), palladium (Pd), platinum (Pt), copper (Cu), chromium (Cr), cobalt (Co), aluminum (Al), zinc (Zn), iron (Fe), iridium (Ir), osmium (Os), rhodium (Rh), tungsten (W), molybdenum (Mo), nickel (Ni), or indium tin oxide (ITO). These may be used alone or as a mixture thereof. For example, the conductive powder may include silver (Ag) powder. The first conductive layer may not include tin powder, bismuth powder, or lead powder.

In some embodiments, in addition to the silver powder, the conductive powder may further include nickel (Ni) powder, cobalt (Co) powder, iron (Fe) powder, zinc (Zn) powder, or copper (Cu) powder.

The glass fit, the organic vehicle, and additives may be the same as described in the second conductive layer.

Substrate

The substrate may include a suitable substrate known to those skilled in the art. For example, the substrate may be formed of crystalline silicon or a compound semiconductor. The crystalline silicon may be monocrystalline or polycrystalline silicon. For example, a silicon wafer may be used as the crystalline silicon.

Manufacture of Front Electrode for Solar Cell

The front electrode may be prepared by a suitable method. For example, the composition for the first conductive layer may coated onto the substrate, followed by drying at about 200° C. to about 400° C. for about 10 seconds to about 60 seconds. Then, the composition for the second conductive layer may be coated onto the composition for the first conductive layer, followed by drying at about 200° C. to about 400° C. for about 10 seconds to about 60 seconds. Then, the resultant may be subjected to baking at about 400° C. to about 950° C., or for example, about 700° C. to about 950° C. for about 30 seconds to about 180 seconds, thereby manufacturing the front electrode for solar cells.

Solar Cell

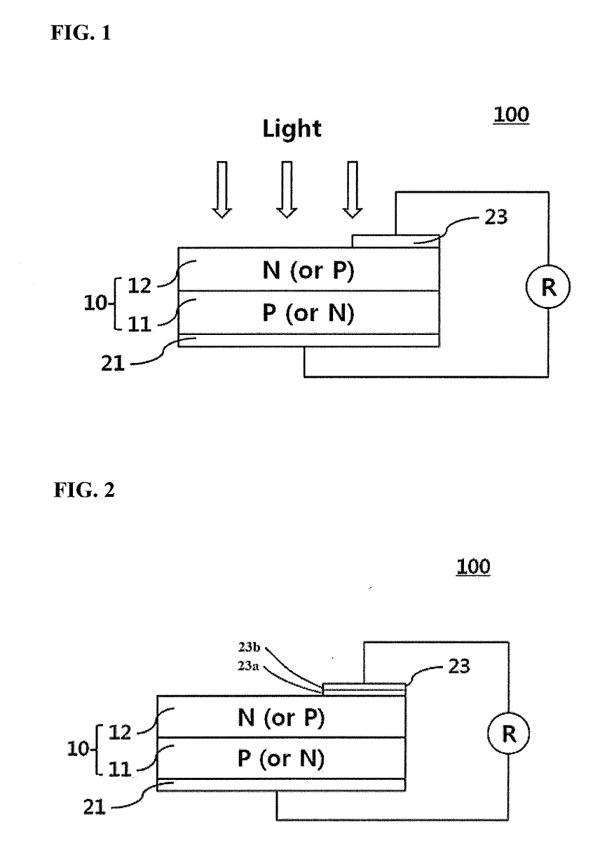

FIGS. 1 and 2 illustrate schematic views of a solar cell according to an embodiment. Referring to FIG. 1, a solar cell 100 may include a substrate 10, a front electrode 23 formed on a front surface of the substrate 10, and a rear electrode 21 formed on a back surface of the substrate 10 The front electrode 23 may be the front electrode described herein. In particular, referring to FIG. 2, the front electrode 23 may include the first conductive layer 23a on the substrate 10 and the second conductive layer 23b on the first conductive layer 23a.

In one implementation, the substrate 10 may be a substrate with a p-n junction formed therein. For example, the substrate 10 may include a semiconductor substrate 11 and an emitter 12. in some implementations, the substrate 10 may be a substrate prepared by doping one surface of a p-type semiconductor substrate 11 with an n-type dopant to form an n-type emitter 12. In some implementations, the substrate 10 may be a substrate prepared by doping one surface of an n-type semiconductor substrate 11 with a p-type dopant to form a p-type emitter 12. The semiconductor substrate 11 may be a p-type substrate or an n-type substrate. The p-type substrate may be a semiconductor substrate 11 doped with a p-type dopant and the n-type substrate may be a semiconductor substrate 11 doped with an n-type dopant.

In description of the substrate 10, the semiconductor substrate 11, and the like, a surface of such a substrate on which light is incident is referred to as the front surface (light receiving surface). A surface of the substrate opposite the front surface is referred to as the back surface.

In one embodiment, the semiconductor substrate 11 may be formed of crystalline silicon or a compound semiconductor. The crystalline silicon may be monocrystalline or polycrystalline silicon. As the crystalline silicon, for example, a silicon wafer may be used.

The p-type dopant may be a material including a group III element such as boron, aluminum, or gallium. In addition, the n-type dopant may be a material including a group V element, such as phosphorus, arsenic or antimony.

The front electrode 23 may be the front electrode according to embodiments described above.

The rear electrode 21 may be manufactured using a composition including aluminum powder as a conductive powder.

The following Examples and Comparative Examples are provided in order to highlight characteristics of one or more embodiments, but it will be understood that the Examples and Comparative Examples are not to be construed as limiting the scope of the embodiments, nor are the Comparative Examples to be construed as being outside the scope of the embodiments. Further, it will be understood that the embodiments are not limited to the particular details described in the Examples and Comparative Examples.

### Example 1

Second Conductive Layer

As an organic binder, ethylcellulose (STD4, Dow Chemical Company) was mixed with butyl carbitol, as a solvent, in amounts as listed in Table 1 and sufficiently dissolved at 60° C. Then, spherical silver powder (AG-4-8, Dowa Hightech Co., Ltd., average particle diameter (D50): 2.0 μm), as a first metal powder; spray-dried tin powder (Mitsui Chemical, average particle diameter (D50): 3.0 μm), as a second metal powder; leaded glass powder A (CI-124, Particlogy Co., Ltd., average particle diameter: 2.0 μm), as a glass frit; leaded glass powder B (CI-5008, Particlogy Co., Ltd., average particle diameter: 1.0 μm) as a glass frit; a dispersant (BYK102, BYK-chemie); and a thixotropic agent (Thixatrol ST, Elementis Co., Ltd.) were added to the binder solution in amounts as listed in Table 1, followed by mixing and kneading in a 3-roll kneader, thereby preparing a composition for the second conductive layer.

First Conductive Layer

As an organic binder, 2 wt % of ethylcellulose (STD4. Dow Chemical Company) was sufficiently dissolved in 5.5 wt % of butyl carbitol at 60° C. Then, 90 wt % of spherical silver powder (AG-4-8, Dowa Hightech Co., Ltd., average particle diameter (D50): 2.0 μm); 1 wt % of leaded glass powder A (leaded glass, CI-124, Particlogy Co., Ltd., average particle diameter: 2.0 μm, glass transition point: 381° C.), as a glass frit; 1 wt % of leaded glass powder B (leaded glass, CI-5008, Particlogy Co., Ltd., average particle diameter: 1.0 μm) as a glass frit; 0.2 wt % of a dispersant (BYK102, BYK-chemie); and 0.3 wt % of a thixotropic agent (Thixatrol ST, Elementis Co., Ltd.) were added to the binder solution, followed by mixing and kneading in a 3-roll kneader, thereby preparing a composition for the first conductive layer.

Solar Cell

The prepared composition for the first conductive layer was deposited over a front surface of a wafer (a mono wafer (average sheet resistance: 80Ω) prepared by texturing a front surface of a p-type wafer doped with boron (B), forming an n⁺ layer of POCl₃ on the textured surface, and forming an antireflective film of SiNx:H on the n⁺ layer) by screen printing in a predetermined pattern, followed by drying in an IR drying furnace at 300° C. to 400° C. Then, the prepared composition for the second conductive layer was printed on the composition for the first conductive layer and dried in the same manner as above.

Then, the content of the second metal powder in the first conductive layer and the second conductive layer was measured by energy dispersive spectrometry (EDS). After EDS mapping on a cross-section of the electrode, the mapping areas of components were compared with one another through an image analysis program to find an area ratio, thereby measuring the content of the second metal powder. Results are shown in Table 2.

Then, an aluminum paste was printed on a back surface of the wafer and dried in the same manner as above. A cell formed according to this procedure was subjected to baking at 950° C. for 30 to 50 seconds in a belt-type baking furnace, thereby manufacturing a solar cell.

### Example 2

A solar cell was manufactured in the same manner as in Example 1 except that the amounts of the first metal powder and the second metal powder were changed as listed in Table 1 (unit: wt %).

### Example 3

A solar cell was manufactured in the same manner as in Example 1 except that spray-dried lead powder (Mitsui Chemical, average particle diameter (D50): 2 μm) was used as the second metal powder.

### Example 4

A solar cell was manufactured in the same manner as in Example 1 except that spray-dried bismuth powder (Mitsui Chemical, average particle diameter (D50): 2 μm) was used as the second metal powder.

### Comparative Example 1

A solar cell was manufactured in the same manner as in Example 1 except that the second conductive layer was the same as the first conductive layer, such that the second conductive layer did not contain the second metal powder.

### Comparative Example 2

A solar cell was manufactured in the same manner as in Example 1 except that the amounts of the first metal powder and the second metal powder were changed as listed in Table 1.

### Comparative Example 3

A solar cell was manufactured in the same manner as in Example 1 except that the amounts of the first metal powder and the second metal powder were changed as listed in Table 1.

### Comparative Example 4

A solar cell was manufactured in the same manner as in Example 1 except that only the second conductive layer was formed on the substrate without forming the first conductive layer.

TABLE 1

| | | Example | | | | Comparative Example | | | |
|---|---|---|---|---|---|---|---|---|---|
| | | 1 | 2 | 3 | 4 | 1 | 2 | 3 | 4 |
| Conductive | Silver | 85 | 80 | 85 | 85 | 90 | 58 | 55 | 85 |
| powder | Tin | 5 | 10 | — | — | — | 32 | 35 | 5 |
| | Lead | — | — | 5 | — | — | — | — | — |
| | Bismuth | — | — | — | 5 | — | — | — | — |
| Organic | Organic binder | 2 | 2 | 2 | 2 | 2 | 2 | 2 | 2 |
| vehicle | Solvent | 5.5 | 5.5 | 5.5 | 5.5 | 5.5 | 5.5 | 5.5 | 5.5 |
| Glass frit | Glass powder A | 1 | 1 | 1 | 1 | 1 | 1 | 1 | 1 |
| | Glass powder B | 1 | 1 | 1 | 1 | 1 | 1 | 1 | 1 |

| | | | | | | | | |
|---|---|---|---|---|---|---|---|---|
| Dispersant | 0.2 | 0.2 | 0.2 | 0.2 | 0.2 | 0.2 | 0.2 | 0.2 |
| Thixotropic agent | 0.3 | 0.3 | 0.3 | 0.3 | 0.3 | 0.3 | 0.3 | 0.3 |
| Total | 100 | 100 | 100 | 100 | 100 | 100 | 100 | 100 |

The solar cells prepared in Examples and Comparative Examples were evaluated as to the following properties. Results are shown in Table 2.

(1) Electrical Properties

Each of the solar cells prepared in Examples and Comparative Examples were evaluated as to fill factor (FF, %) and conversion efficiency (Eff, %) using a solar cell efficiency tester (CT-801, Pasan Co., Ltd.).

(2) Tensile Strength

Tensile strength of each of the solar cells prepared in Examples and Comparative Examples was measured at 180 degrees using a tensile tester.

TABLE 2

| | Example | | | | Comparative Example | | | |
|---|---|---|---|---|---|---|---|---|
| | 1 | 2 | 3 | 4 | 1 | 2 | 3 | 4 |
| Amount of second metal | 2.5 | 5 | 2.5 | 2.5 | 0 | 16 | 17.5 | 5 |
| powder (wt %) | | | | | | | | |
| FF (%) | 77.9 | 77.6 | 77.4 | 77.3 | 80.1 | 77.4 | 69.4 | 64.7 |
| Eff (%) | 17.48 | 17.44 | 17.43 | 17.41 | 17.45 | 17.12 | 16.78 | 15.41 |
| Tensile strength (N/mm) | 2.8 | 3.0 | 4.3 | 3.7 | 2.0 | 2.3 | 1.9 | 2.9 |

Amount of second metal powder: Amount of second metal powder based on total weight of first conductive layer and second conductive layer

As shown in Table 2, the solar cells including the front electrode according to embodiments exhibited an electrical efficiency higher than or equal to that of Comparative Example 1, which included the same amount of silver powder instead of the second metal powder, while exhibiting increased tensile strength. As described above, by increasing the tensile strength, long-term reliability of a solar cell can be improved. Conversely, Comparative Example 1, which did not include the second metal powder, exhibited poor tensile strength. Comparative Example 2 and Comparative Example 3 in which the content of the second metal powder was out of the specified range according embodiments exhibited a deterioration in efficiency due to an increase in resistance and a reduction in tensile strength. Comparative Example 4, which included the second metal powder but did not include the first conductive layer, exhibited a deterioration in efficiency due to an increase of resistance.

By way of summation and review, electrodes of a solar cell may be fabricated by applying an electrode paste including a conductive powder, a glass frit, and an organic vehicle to a surface of a wafer, followed by patterning and baking. In order to increase efficiency of the solar cell, bi-layer printing may be used. In bi-layer printing, the same paste may be used for first and second layers. The paste may include silver powder.

In order to increase efficiency of the solar cell, it is desirable to lower resistance of printed electrodes. In addition, it is desirable for solar cells to have good long-term reliability.

Generally, a method of changing a glass frit or improving printability of an electrode paste may be considered to lower the resistance of electrodes in a cell employing bi-layer printing.

Embodiments provide a front electrode for a solar cell that can improve the long-term reliability of the solar cell by increasing tensile strength of the solar cell while maintaining cell efficiency higher than or equal to that of a front electrode including only silver powder as a conductive powder for a given amount of the conductive powder.

Embodiments also provide a front electrode for a solar cell that allows for a reduced sintering temperature, thereby improving sinterability in forming the front electrode.

Embodiments also provide a solar cell including the front electrode.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope thereof the present invention as set forth in the following claims.

What is claimed is:

1. A front electrode for a solar cell, the front electrode comprising:
a substrate;
a first conductive layer on the substrate; and
a second conductive layer on the first conductive layer,
wherein:
the second conductive layer is formed of a composition including silver powder as a first metal powder, and at least one of tin powder, lead powder, and bismuth powder as a second metal powder, and
the second metal powder is present in an amount of about 0.1 wt % to about 15 wt % based on the total weight of the first conductive layer and the second conductive layer in an unbaked state of the first conductive layer and the second conductive layer.

2. The front electrode for a solar cell as claimed in claim 1, wherein the second metal powder has an average particle diameter (D50) of about 0.1 μm to about 3 μm.

3. The front electrode for a solar cell as claimed in claim 1, wherein the composition from which the second conductive layer is formed includes about 60 wt % to about 95 wt % of the first metal powder, about 0.1 wt % to about 20 wt % of the second metal powder, about 0.5 wt % to about 20 wt % of a glass frit, and about 1 wt % to about 30 wt % of an organic vehicle.

4. The front electrode for a solar cell as claimed in claim 1, wherein the composition further includes at least one additive of a dispersant, a thixotropic agent, a plasticizer, a viscosity stabilizer, an anti-foaming agent, a pigment, a UV stabilizer, an antioxidant, and a coupling agent.

5. The front electrode for a solar cell as claimed in claim 1, wherein the first conductive layer is formed of a composition that includes the first metal powder and does not include the second metal powder.

6. A solar cell comprising the front electrode for a solar cell as claimed in claim 1.

7. A solar cell comprising the front electrode for a solar cell as claimed in claim 2.

8. A solar cell comprising the front electrode for a solar cell as claimed in claim 3.

9. A solar cell comprising the front electrode for a solar cell as claimed in claim 4.

10. A solar cell comprising the front electrode for a solar cell as claimed in claim 5.
